(19) United States
(12) Patent Application Publication
(10) Pub. No.: US 2025/0111112 A1
(43) Pub. Date: Apr. 3, 2025

(54) TRANSFORMER MODEL-BASED CLUSTERING TECHNIQUES FOR STANDARD CELL DESIGN AUTOMATION

(71) Applicant: NVIDIA CORPORATION, Santa Clara, CA (US)

(72) Inventors: Chia-Tung HO, Santa Clara, CA (US); Haoxing REN, Austin, TX (US)

(21) Appl. No.: 18/637,636

(22) Filed: Apr. 17, 2024

Related U.S. Application Data
(60) Provisional application No. 63/586,357, filed on Sep. 28, 2023.

(51) Int. Cl. G06F 30/323

(52) U.S. Cl. CPC G06F 30/323

(57) ABSTRACT

Various embodiments are directed towards techniques for automatically generating standard cell layouts. In various embodiments, those techniques include processing a netlist graph to generate a plurality of graph embeddings, processing the plurality graph embedding via a transformer model to generate a plurality of device component embeddings, generating a page rank value for each device included in the netlist graph based on the plurality of device component embeddings, performing one or more clustering operations on the page rank values to generate a plurality of device clusters, and performing one or more standard cell synthesis operations using labels for the plurality of device clusters to generate at least one standard cell layout for the netlist graph.

### CROSS-REFERENCE TO RELATED APPLICATIONS

This application claims priority benefit of the United States Provisional Patent Application titled, “TRANSFORMER MODEL-BASED CLUSTERING TECHNIQUES FOR STANDARD CELL DESIGN AUTOMATION,” filed on Sep. 28, 2023, and having Ser. No. 63/586,357. The subject matter of these related applications is hereby incorporated herein by reference.

### BACKGROUND

### Field of the Various Embodiments

The various embodiments relate generally to computer science, circuit design, and artificial intelligence and, more specifically, transformer model-based clustering for standard cell design automation.

### Description of the Related Art

Integrated circuits are commonly designed as a collection of standard cells. A standard cell is a group of transistors and interconnected structures that typically provides some type of Boolean logic or storage function. Designing circuits as a collection of standard cells enables designers to solve the problems of abstract logic design and physical semiconductor layout separately. Among other things, when designing a circuits, standard cell designers are tasked with placing circuit components and connecting those components according to the logical design rules in a process known as “routing.” When designing plans to place and route standard cell components, designers seek to maximize the space and energy efficiencies of the circuits they are designing while satisfying the related computational requirements.

Standard cell design is becoming far more challenging as circuits, and therefore standard cells, become smaller. In particular, designers are tasked with implementing more complex standard cell designs in smaller footprints, which makes routing far more difficult. In this regard, smaller standard cells have fewer routing pathways by which to connect components. Therefore, designers typically have to experiment with many different component placements before finding a routable solution that satisfies the circuit logic. Experienced human standard cell designers are struggling to deliver standard cell libraries efficiently, if at all, due to these types of challenges. Accordingly, designers are increasingly turning to automated techniques for standard cell design.

Sequential standard cell synthesis is an automated technique for standard cell design that first proposes transistor placements for a given circuit and then attempts to find a routing solution based on those transistor placements. With this type of technique, a first algorithm is usually implemented to place transistors within the circuit in a way that most efficiently satisfies the applicable design rules for the circuit. Subsequently, a different algorithm is usually implemented to search for a set of routing connections that do not violate any of the applicable design rules. In so doing, these algorithms have to simultaneously incorporate the local details of a particular standard cell and the context of the circuit into which the standard cell is being placed. Successfully incorporating information from multiple different scales into an overall circuit design can sometimes be difficult for the algorithms that are typically implemented in sequential standard cell synthesis. Therefore, with sequential standard cell synthesis design approaches, there is no guarantee that a given proposed placement has a routable solution. Consequently, multiple design iterations may be required before a solution is found.

Simultaneous standard cell synthesis is another automated technique where transistors are placed and routed simultaneously to generate a given circuit. Because placement and routing are solved in tandem, simultaneous standard cell synthesis design approaches tend to ensure routable solutions. However, simultaneous standard cell synthesis is complex and can require substantial computational resources, particularly when designing complex circuits. Further, simultaneous standard cell synthesis does not scale very well, which limits the usefulness of this approach, particularly when designing for complex circuits.

As the foregoing illustrates, what is needed in the art are more effective techniques for designing circuits using standard cells.

### SUMMARY

Various embodiments are directed towards techniques for automatically generating standard cell layouts. In various embodiments, those techniques include processing a netlist graph to generate a plurality of graph embeddings, processing the plurality graph embedding via a transformer model to generate a plurality of device component embeddings, generating a page rank value for each device included in the netlist graph based on the plurality of device component embeddings, performing one or more clustering operations on the page rank values to generate a plurality of device clusters, and performing one or more standard cell synthesis operations using labels for the plurality of device clusters to generate at least one standard cell layout for the netlist graph.

One technical advantage of the disclosed techniques relative to the prior art is that the disclosed techniques enable integrated circuit designs that incorporate standard cells to be automatically generated in a way that can be more computationally efficient and scalable relative to prior art approaches. Accordingly, the disclosed techniques allow integrated circuits to be automatically designed to have smaller transistor and component sizes and, accordingly, greater complexity relative to what is achievable using prior art approaches. Another technical advantage of the disclosed techniques is the incorporation of circuit-scale information within standard cells, which enables more effective routing when automatically designing integrated circuits. Further, implementing transformer models allows more effective transistor placement within a given circuit relative to prior art techniques, which can result in a greater number of routable design options and a more optimized overall circuit design. These technical advantages provide one or more technological improvements over prior art approaches.

### BRIEF DESCRIPTION OF THE DRAWINGS

So that the manner in which the above recited features of the various embodiments can be understood in detail, a more particular description of the inventive concepts, briefly summarized above, may be had by reference to various embodiments, some of which are illustrated in the appended drawings. It is to be noted, however, that the appended drawings illustrate only typical embodiments of the inventive concepts and are therefore not to be considered limiting of scope in any way, and that there are other equally effective embodiments.

FIG. 1 illustrates a block diagram of a computer-based system configured to implement one or more aspects of the various embodiments;

FIG. 2 is a more detailed illustration of the machine learning server of FIG. 1 that is configured to implement the model trainer, according to various embodiments;

FIG. 3 is a more detailed illustration of the computing device of FIG. 1 that is configured to implement the standard cell generating application, according to various embodiments;

FIG. 4 is a more detailed illustration of the standard cell generating application of FIG. 1, according to various embodiments;

FIG. 5 is a more detailed illustration of the transformer model of FIG. 1, according to various embodiments;

FIG. 6 is a more detailed illustration of one of the encoding layers of FIG. 5, according to various embodiments;

FIG. 7 is a more detailed illustration of one of the attention modules of FIG. 6, according to various embodiments;

FIG. 8 is a more detailed illustration of the PageRank module of FIG. 4, according to various embodiments;

FIG. 9 is a more detailed illustration of the model trainer of FIG. 1, according to various embodiments;

FIG. 10 is a flow diagram of method steps for generating layout graphs from netlist graphs, according to various embodiments;

FIG. 11 is a flow diagram of method steps for generating PageRank rankings for devices, according to various embodiments; and

FIG. 12 is a flow diagram of method steps for the unsupervised training of a transformer model on netlist graphs, according to various embodiments.

### DETAILED DESCRIPTION

In the following description, numerous specific details are set forth to provide a more thorough understanding of the various embodiments. However, it will be apparent to one of skilled in the art that the inventive concepts may be practiced without one or more of these specific details.

### General Overview

Various techniques are described herein for transformer model-based clustering for standard cell design automation. In some embodiments, a netlist logic graph is passed through a graph network model to summarize the logical structure of the netlist graph in graph embeddings. Those graph embeddings then serve as inputs to a transformer model. The transformer model is modified to include additional linear bias terms that incorporate information about the spatial and device placement relationships between netlist graph nodes, and the transformer model is trained on netlist and layout graphs from routable standard cells in an unsupervised fashion using a similarity loss. Upon receiving netlist graph embeddings as input, the transformer model produces device component embeddings for the netlist graph components. The device component embeddings are combined with the transition matrix of the netlist logic graph to create page rank coordinates for each device included in the netlist logic graph. Device clusters are then found based on the page rank coordinates using a clustering algorithm, such as DBScan. Labels for the device clusters are then incorporated into the optimization criteria for a set of sequential standard cell synthesis operations in order to generate one or more standard cell layouts for the initial netlist logic graph.

The above operations and features are not in any way intended to be limiting. As persons skilled in the art will appreciate, as a general matter, the techniques described herein can be implemented in various ways and still remain within the scope of the various embodiments.

### System Overview

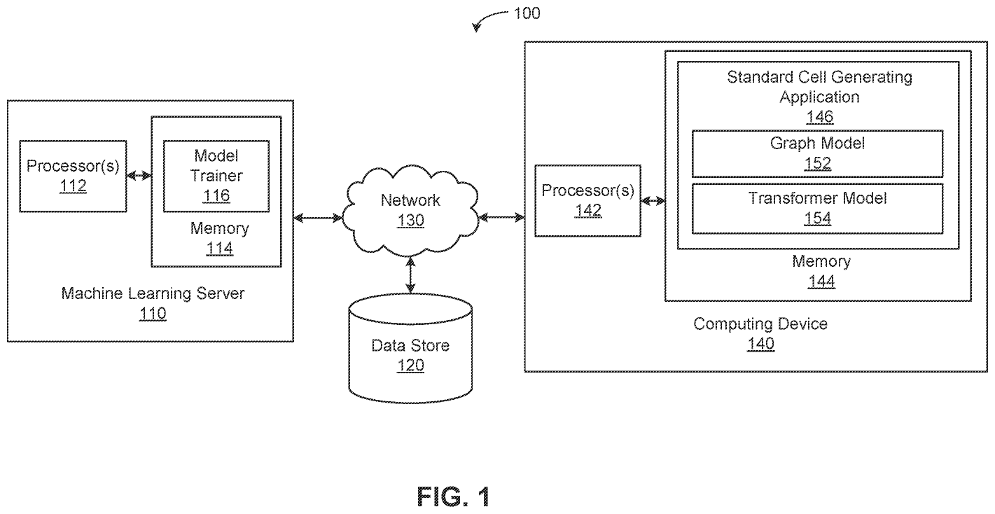

FIG. 1 illustrates a block diagram of a computer-based system 100 configured to implement one or more aspects of the various embodiments. As shown, the system 100 includes, without limitation, a machine learning server 110, a data store 120, and a computing device 140 in communication over a network 130, which can be a wide area network (WAN) such as the internet, a local area network (LAN), a cellular network, and/or any other suitable network.

As also shown, a model trainer 116 executes on one or more processors 112 of the machine learning server 110 and is stored in a system memory 114 of the machine learning server 110. The processor 112 receives user input from input devices, such as a keyboard or a mouse. In operation, the one or more processors 112 may include one or more primary processors of the machine learning server 110, controlling and coordinating operations of other system components. In particular, the processor(s) 112 can issue commands that control the operation of one or more graphics processing units (GPUs) (not shown) and/or other parallel processing circuitry (e.g., parallel processing units, deep learning accelerators, etc.) that incorporates circuitry optimized for graphics and video processing, including, for example, video output circuitry. The GPU(s) can deliver pixels to a display device that can be any conventional cathode ray tube, liquid crystal display, light-emitting diode display, and/or the like.

The system memory 114 of the machine learning server 110 stores content, such as software applications and data, for use by the processor(s) 112 and the GPU(s) and/or other processing units. The system memory 114 can be any type of memory capable of storing data and software applications, such as a random-access memory (RAM), a read-only memory (ROM), an erasable programmable read-only memory (EPROM or flash ROM), or any suitable combination of the foregoing. In some embodiments, a storage (not shown) can supplement or replace the system memory 114. The storage can include any number and type of external memories that are accessible to the processor 112 and/or the GPU. For example, and without limitation, the storage can include a secure digital card, an external flash memory, a portable compact disc read-only memory (CD-ROM), an optical storage device, a magnetic storage device, and/or any suitable combination of the foregoing.

The machine learning server 110 shown herein is for illustrative purposes only, and variations and modifications are possible without departing from the scope of the present disclosure. For example, the number of processors 112, the number of GPUs and/or other processing unit types, the number of system memories 114, and/or the number of applications included in the system memory 114 can be modified as desired. Further, the connection topology between the various units in FIG. 1 can be modified as desired. In some embodiments, any combination of the processor(s) 112, the system memory 114, and/or GPU(s) can be included in and/or replaced with any type of virtual computing system, distributed computing system, and/or cloud computing environment, such as a public, private, or a hybrid cloud system.

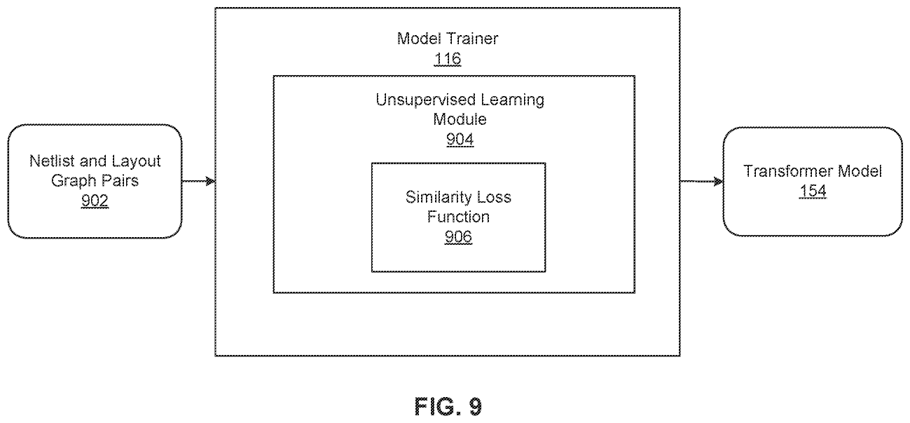

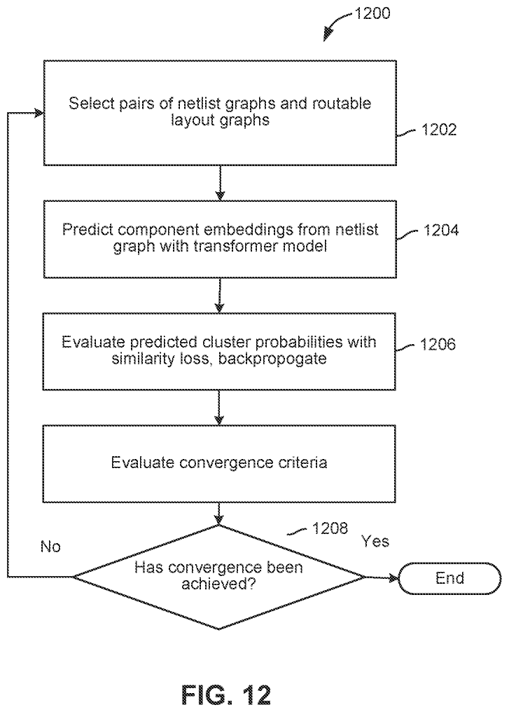

In some embodiments, the model trainer 116 is configured to train one or more machine learning models, including a transformer model 154. Techniques that the model trainer 116 can use to train the machine learning model(s) are discussed in greater detail below in conjunction with FIGS. 9 and 12. Training data and/or trained (or deployed) machine learning models, including the transformer model 154, can be stored in the data store 120. In some embodiments, the data store 120 can include any storage device or devices, such as fixed disc drive(s), flash drive(s), optical storage, network attached storage (NAS), and/or a storage area-network (SAN). Although shown as accessible over the network 130, in at least one embodiment, the machine learning server 110 can include the data store 120.

In addition, a standard cell generating application 146 that implements graph model 152 and transformer model 154 is stored in a system memory 114, and executes on a processor 112, of the computing device 140. Once trained, transformer model 154 can be deployed in any suitable manner, such as via standard cell generating application 146.

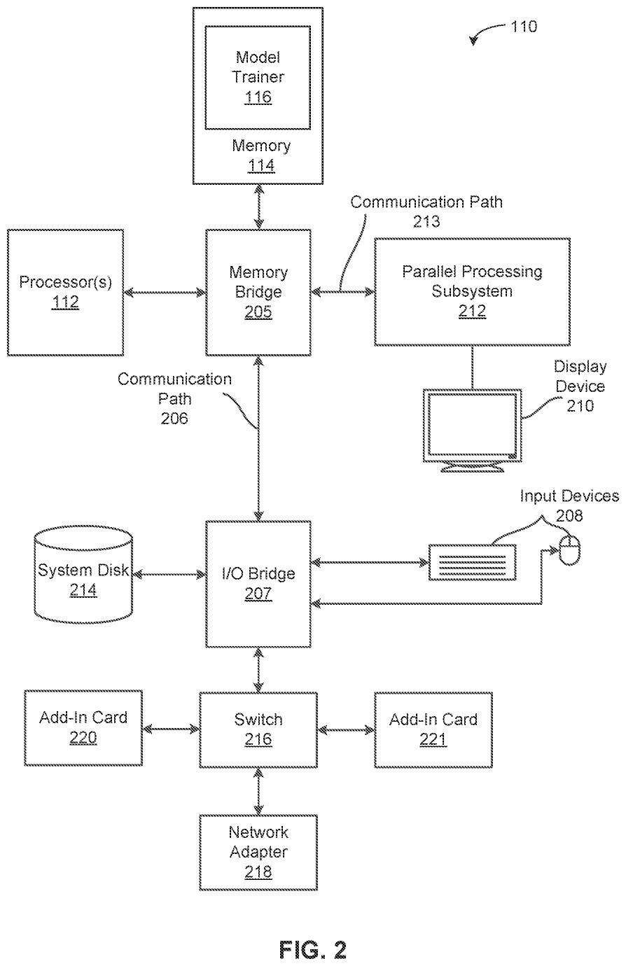

FIG. 2 is a more detailed illustration of the machine learning server 110 of FIG. 1 that is configured to implement the model trainer 116, according to various embodiments. Machine learning server 110 may include any type of computing system, including, without limitation, a server machine, a server platform, a desktop machine, a laptop machine, a hand-held/mobile device, a digital kiosk, an in-vehicle infotainment system, and/or a wearable device. In some embodiments, machine learning server 110 is a server machine operating in a data center or a cloud computing environment that provides scalable computing resources as a service over a network.

In various embodiments, machine learning server 110 includes, without limitation, the processor(s) 112 and the memory (IES) 114 coupled to a parallel processing subsystem 212 via a memory bridge 205 and a communication path 213. Memory bridge 205 is further coupled to an I/O (input/output) bridge 207 via a communication path 206, and I/O bridge 207 is, in turn, coupled to a switch 216.

In one embodiment, I/O bridge 207 is configured to receive user input information from optional input devices 208, such as a keyboard, mouse, touch screen, sensor data analysis (e.g., Evaluating gestures, speech, or other information about one or more uses in a field of view or sensory field of one or more sensors), and/or the like, and forward the input information to the processor(s) 112 for processing. In some embodiments, machine learning server 110 may be a server machine in a cloud computing environment. In such embodiments, machine learning server 110 may not include input devices 208 but may receive equivalent input information by receiving commands (e.g., responsive to one or more inputs from a remote computing device) in the form of messages transmitted over a network and received via the network adapter 218. In some embodiments, switch 216 is configured to provide connections between I/O bridge 207 and other components of the machine learning server 110, such as a network adapter 218 and various add-in cards 220 and 221.

In some embodiments, I/O bridge 207 is coupled to a system disk 214 that may be configured to store content and applications and data for use by processor(s) 112 and parallel processing subsystem 212. In one embodiment, system disk 214 provides non-volatile storage for applications and data and may include fixed or removable hard disk drives, flash memory devices, and CD-ROM (compact disc read-only-memory), DVD-ROM (digital versatile disc-rom), Blu-ray, HD-DVD (high-definition DVD), or other magnetic, optical, or solid state storage devices. In various embodiments, other components, such as universal serial bus or other port connections, compact disc drives, digital versatile disc drives, film recording devices, and the like, may be connected to I/O bridge 207 as well.

In various embodiments, memory bridge 205 may be a northbridge chip, and I/O bridge 207 may be a southbridge chip. In addition, communication paths 206 and 213, as well as other communication paths within machine learning server 110, may be implemented using any technically suitable protocols, including, without limitation, AGP(accelerated graphics port), hypertransport, or any other bus or point-to-point communication protocol known in the art.

In some embodiments, parallel processing subsystem 212 comprises a graphics subsystem that delivers pixels to an optional display device 210 that may be any conventional cathode ray tube, liquid crystal display, light-emitting diode display, and/or the like. In such embodiments, the parallel processing subsystem 212 may incorporate circuitry optimized for graphics and video processing, including, for example, video output circuitry. Such circuitry may be incorporated across one or more parallel processing units (PPUs), also referred to herein as parallel processors, included within the parallel processing subsystem 212.

In some embodiments, the parallel processing subsystem 212 incorporates circuitry optimized (e.g., That undergoes optimization) for general purpose and/or compute processing. Again, such circuitry may be incorporated across one or more PPUs included within parallel processing subsystem 212 that are configured to perform such general purpose and/or compute operations. In yet other embodiments, the one or more PPUs included within parallel processing subsystem 212 may be configured to perform graphics processing, general purpose processing, and/or compute processing operations. System memory 114 includes at least one device driver configured to manage the processing operations of the one or more PPUs within parallel processing subsystem 212. In addition, the system memory 114 includes the model trainer 116. Although described herein primarily with respect to the model trainer 116, techniques disclosed herein can also be implemented, either entirely or in part, in other software and/or hardware, such as in the parallel processing subsystem 212.

In various embodiments, parallel processing subsystem 212 may be integrated with one or more of the other elements of FIG. 2 to form a single system. For example, parallel processing subsystem 212 may be integrated with processor 112 and other connection circuitry on a single chip to form a system on a chip (soc).

In some embodiments, processor(s) 112 includes the primary processor of machine learning server 110, controlling and coordinating operations of other system components. In some embodiments, the processor(s) 112 issues commands that control the operation of PPUs. In some embodiments, communication path 213 is a PCI express link, in which dedicated lanes are allocated to each PPU. Other communication paths may also be used. The PPU advantageously implements a highly parallel processing architecture, and the PPU may be provided with any amount of local parallel processing memory (pp memory).

It will be appreciated that the system shown herein is illustrative and that variations and modifications are possible. The connection topology, including the number and arrangement of bridges or the number of parallel processing subsystems 212, may be modified as desired. For example, in some embodiments, system memory 114 could be connected to the processor(s) 112 directly rather than through memory bridge 205, and other devices may communicate with system memory 114 via memory bridge 205 and processor 112. In other embodiments, parallel processing subsystem 212 may be connected to I/O bridge 207 or directly to processor 112, rather than to memory bridge 205. In still other embodiments, I/O bridge 207 and memory bridge 205 may be integrated into a single chip instead of existing as one or more discrete devices. In certain embodiments, one or more components shown in FIG. 2 may not be present. For example, switch 216 could be eliminated, and network adapter 218 and add-in cards 220, 221 would connect directly to I/O bridge 207. Lastly, in certain embodiments, one or more components shown in FIG. 2 may be implemented as virtualized resources in a virtual computing environment, such as a cloud computing environment. In particular, the parallel processing subsystem 212 may be implemented as a virtualized parallel processing subsystem in at least one embodiment. For example, the parallel processing subsystem 212 may be implemented as a virtual graphics processing unit(s) (VPU(s)) that renders graphics on a virtual machine(s) (VM(s)) executing on a server machine(s) whose GPU(s) and other physical resources are shared across one or more VMs.

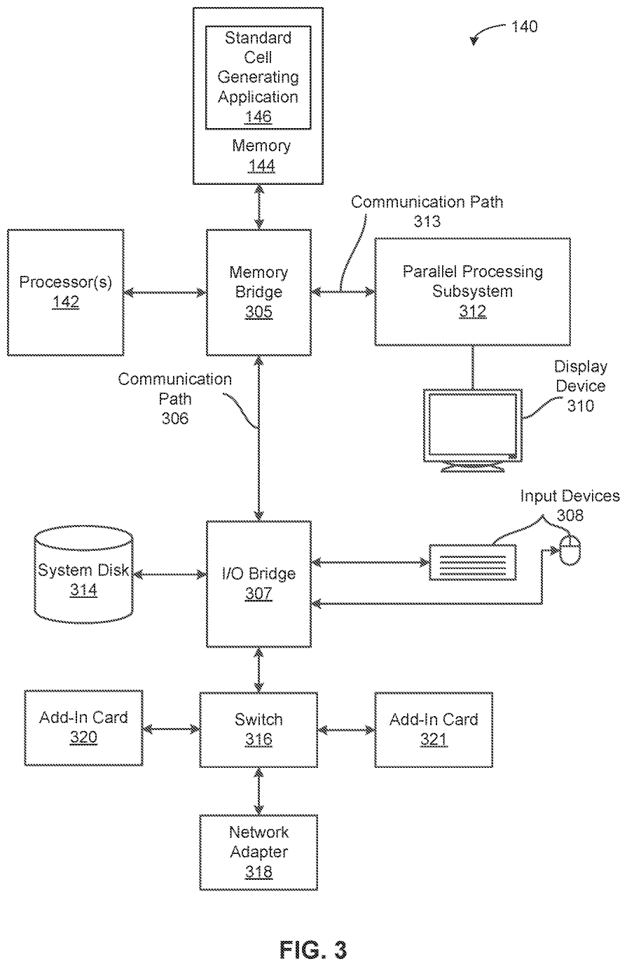

FIG. 3 is a more detailed illustration of the computing device 140 of FIG. 1 that is configured to implement the standard cell generating application 146, according to various embodiments. Computing device 140 may include any type of computing system, including, without limitation, a server machine, a server platform, a desktop machine, a laptop machine, a hand-held/mobile device, a digital kiosk, an in-vehicle infotainment system, and/or a wearable device. In some embodiments, computing device 140 is a server machine operating in a data center or a cloud computing environment that provides scalable computing resources as a service over a network.

In various embodiments, the computing device 140 includes, without limitation, the processor(s) 142 and the memory (IES) 144 coupled to a parallel processing subsystem 312 via a memory bridge 305 and a communication path 313. Memory bridge 305 is further coupled to an I/O (input/output) bridge 307 via a communication path 306, and I/O bridge 307 is, in turn, coupled to a switch 316.

In one embodiment, I/O bridge 307 is configured to receive user input information from optional input devices 308, such as a keyboard, mouse, touch screen, sensor data analysis (e.g., Evaluating gestures, speech, or other information about one or more uses in a field of view or sensory field of one or more sensors), and/or the like, and forward the input information to the processor(s) 142 for processing. In some embodiments, the computing device 140 may be a server machine in a cloud computing environment. In such embodiments, computing device 140 may not include input devices 308, but may receive equivalent input information by receiving commands (e.g., Responsive to one or more inputs from a remote computing device) in the form of messages transmitted over a network and received via the network adapter 318. In some embodiments, switch 316 is configured to provide connections between I/O bridge 307 and other components of the standard cell generating application 146, such as a network adapter 318 and various add-in cards 320 and 321.

In some embodiments, I/O bridge 307 is coupled to a system disk 314 that may be configured to store content and applications and data for use by processor(s) 142 and parallel processing subsystem 312. In one embodiment, system disk 314 provides non-volatile storage for applications and data and may include fixed or removable hard disk drives, flash memory devices, and CD-ROM (compact disc read-only-memory), DVD-ROM (digital versatile disc-rom), Blu-ray, HD-DVD (high-definition DVD), or other magnetic, optical, or solid state storage devices. In various embodiments, other components, such as universal serial bus or other port connections, compact disc drives, digital versatile disc drives, film recording devices, and the like, may be connected to I/O bridge 307 as well.

In various embodiments, memory bridge 305 may be a northbridge chip, and I/O bridge 307 may be a southbridge chip. In addition, communication paths 306 and 313, as well as other communication paths within standard cell generating application 146, may be implemented using any technically suitable protocols, including, without limitation, AGP (accelerated graphics port), hypertransport, or any other bus or point-to-point communication protocol known in the art.

In some embodiments, parallel processing subsystem 312 comprises a graphics subsystem that delivers pixels to an optional display device 310 that may be any conventional cathode ray tube, liquid crystal display, light-emitting diode display, and/or the like. In such embodiments, the parallel processing subsystem 312 may incorporate circuitry optimized for graphics and video processing, including, for example, video output circuitry. Such circuitry may be incorporated across one or more parallel processing units (PPUs), also referred to herein as parallel processors, included within the parallel processing subsystem 312.

In some embodiments, the parallel processing subsystem 312 incorporates circuitry optimized (e.g., That undergoes optimization) for general purpose and/or compute processing. Again, such circuitry may be incorporated across one or more PPUs included within parallel processing subsystem 312 that are configured to perform such general purpose and/or compute operations. In yet other embodiments, the one or more PPUs included within parallel processing subsystem 312 may be configured to perform graphics processing, general purpose processing, and/or compute processing operations. System memory 144 includes at least one device driver configured to manage the processing operations of the one or more PPUs within parallel processing subsystem 312. In addition, the system memory 144 includes the model trainer 116. Although described herein primarily with respect to the model trainer 116, techniques disclosed herein can also be implemented, either entirely or in part, in other software and/or hardware, such as in the parallel processing subsystem 312.

In various embodiments, parallel processing subsystem 312 may be integrated with one or more of the other elements of FIG. 3 to form a single system. For example, parallel processing subsystem 312 may be integrated with processor 142 and other connection circuitry on a single chip to form a system on a chip (soc).

In some embodiments, processor(s) 142 includes the primary processor of standard cell generating application 146, controlling and coordinating operations of other system components. In some embodiments, the processor(s) 142 issues commands that control the operation of PPUs. In some embodiments, communication path 313 is a PCI express link, in which dedicated lanes are allocated to each PPU. Other communication paths may also be used. The PPU advantageously implements a highly parallel processing architecture, and the PPU may be provided with any amount of local parallel processing memory (pp memory).

It will be appreciated that the system shown herein is illustrative and that variations and modifications are possible. The connection topology, including the number and arrangement of bridges or the number of parallel processing subsystems 312, may be modified as desired. For example, in some embodiments, system memory 144 could be connected to the processor(s) 142 directly rather than through memory bridge 305, and other devices may communicate with system memory 144 via memory bridge 305 and processor 142. In other embodiments, parallel processing subsystem 312 may be connected to I/O bridge 307 or directly to processor 142, rather than to memory bridge 305. In still other embodiments, I/O bridge 307 and memory bridge 305 may be integrated into a single chip instead of existing as one or more discrete devices. In certain embodiments, one or more components shown in FIG. 3 may not be present. For example, switch 316 could be eliminated, and network adapter 318 and add-in cards 320, 321 would connect directly to I/O bridge 307. Lastly, in certain embodiments, one or more components shown in FIG. 3 may be implemented as virtualized resources in a virtual computing environment, such as a cloud computing environment. In particular, the parallel processing subsystem 312 may be implemented as a virtualized parallel processing subsystem in at least one embodiment. For example, the parallel processing subsystem 312 may be implemented as a virtual graphics processing unit(s) (VPU(s)) that renders graphics on a virtual machine(s) (VM(s)) executing on a server machine(s) whose GPU(s) and other physical resources are shared across one or more VMs.

### Transformer-Based Clustering for Standard Cell Design Automation

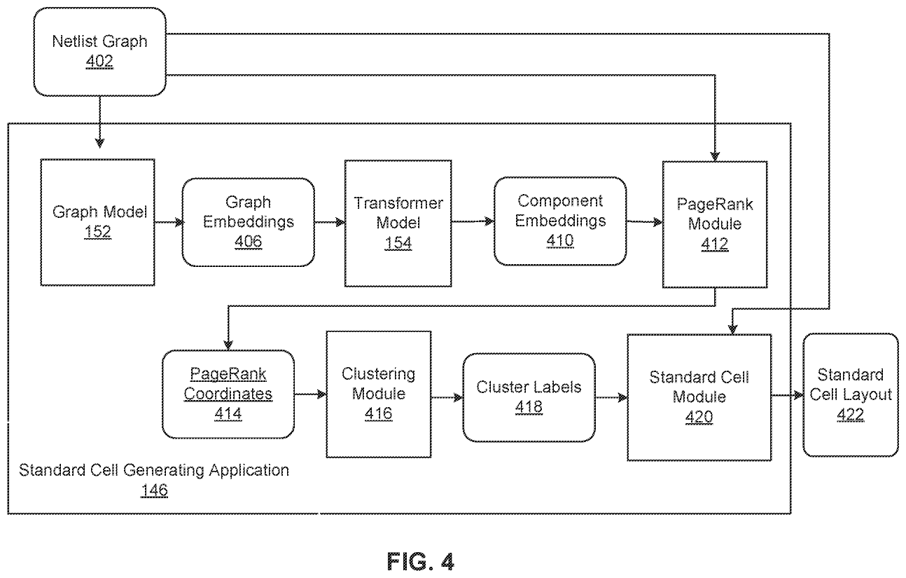

FIG. 4 is a more detailed illustration of the standard cell generating application 146 of FIG. 1, according to various embodiments. As shown, the standard cell generating application 146 includes a graph model 152, a transformer model 154, a PageRank module 412, a clustering module 416, and a standard cell module 420 that operate sequentially to generate standard cell layout 422 the based on input netlist graph 402.

Netlist graph 402 is a representation of the logical design requirements for an integrated circuit design. In various embodiments, netlist graph 402 may be constructed from a spice netlist, where the devices on the graph are represented as nodes, and the edges between the nodes are derived from the different types of connections (e.g., source-to-net, net-to-gate). In operation, graph model 152 accepts netlist graph 402 as input and generates graph embeddings 406. In some embodiments, graph model 152 is a pre-trained GINE graph neural network, but, in other embodiments, graph model 152 can be any model that accepts a graph structure as input and produces vector embeddings describing the graph structure as output. Graph model 152 may accept various properties of netlist graph 402 as inputs to produce graph embeddings 406. For example, node type, device properties, device connectivity, device logic level, and edge properties, could all serve as inputs to graph model 152. Graph embeddings 406 produced by graph model 152 include information about netlist graph 402 that is interpretable by transformer model 154.

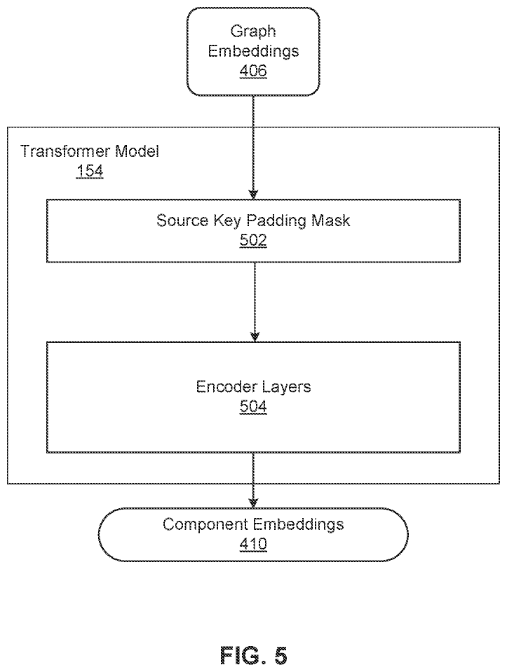

Transformer model 154 accepts graph embeddings 406 received from graph model 152 as inputs and generates component embeddings 410. As described in greater detail below in conjunction with FIG. 5, to generate component embeddings 410, transformer model 154 maps information pertaining to the logical structure of netlist graph 406 to an embedding space. In so doing, transformer model 154 places devices included in netlist graph 406 that should reside closer to one another in standard cell layout 422 closer to one another within the embedding space.

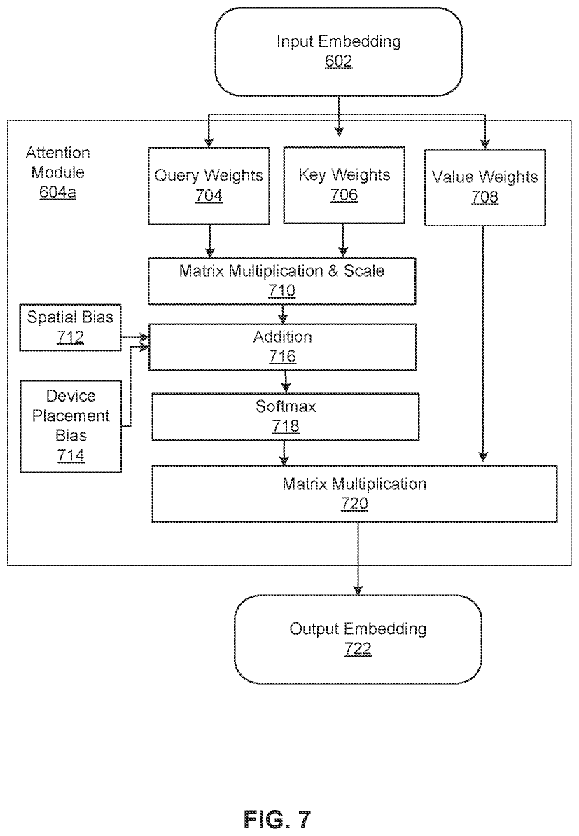

The component embeddings 410 produced by transformer model 154 are processed into a more clustering-friendly format by PageRank module 412. In this regard, and as described in greater detail below in conjunction with FIG. 7, PageRank module 412 iteratively applies a PageRank algorithm to component embeddings 410 to produce PageRank coordinates 414. Clustering module 416 accepts PageRank coordinates 414 as inputs and generates cluster labels 418. In some embodiments, clustering module 416 implements the DBSCAN clustering algorithm, but, in other embodiments, any technically feasible clustering algorithm may be implemented.

Standard cell module 420 accepts cluster labels 416 as inputs along with the original netlist 402 and generates the standard cell layout 422. Standard cell module 418 can implement any standard cell generating procedure that has been modified to accept cluster labels 416 as input. For example, a device clustering cost term that counts the number of devices not included within a current cluster in a given region could be added to the objective function of standard cell generating algorithm and implemented in standard cell module 418. Other algorithms that could be used for this type of modification include, without limitation, tree-based methods, simulated annealing, or NVCell.

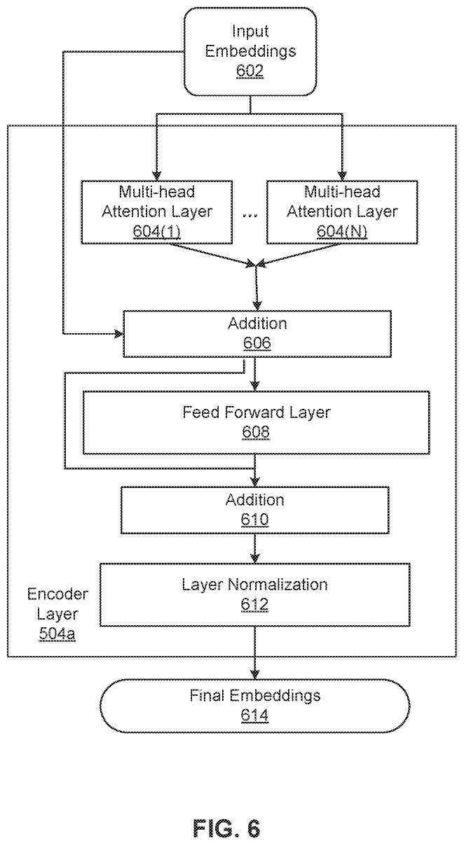

FIG. 5 is a more detailed illustration of the transformer model 154 of FIG. 1, according to various embodiments. As described above, in operation, transformer model 154 accepts graph embeddings 406 as an input and generates component embeddings 410 as output. As shown, transformer model 154 includes source key padding mask 502 and encoder layers 504. Source key padding mask 502 accepts graph embeddings 406 as an input and marks which elements of the graph embeddings 406 correspond to valid data, as opposed to padding zeros. The padded graph embeddings are then passed to encoder layers 504. As described in greater detail below in conjunction with FIG. 6, encoder layers 504 include multiple sequential encoder layers that apply a multi-head attention algorithm to identify device substructures included in the padded graph embeddings. Each layer of encoder layers 504 produces an internal embedding which identifies and groups devices that are structurally similar. Each subsequent layer of encoder layers 504 captures increasingly higher-level structural information included in the original netlist graph 402. The output of the final layer of encoder layers 504 is component embeddings 410.

FIG. 6 is a more detailed illustration of one of the encoding layers 504a of FIG. 5, according to various embodiments. As described above, each encoder layer 504 accepts input embedding 602 as input and produces an output embedding 614 as an output. In various embodiments, input embeddings 602 can correspond to graph embeddings 406 or output embedding 614 of the preceding encoder layer included in encoder layers 504. Similarly, hidden output embedding 614 can correspond to input embedding 602 to the next encoder layer included in encoder layers 504 or component embeddings 410 for the final encoder layer included in encoder layers 504.

As shown, during operation, input embeddings 602 are passed to multi-head attention layers 604 (1-N) included in encoder layer 504a. In various embodiments, any number of multi-head attention layers 604 can be configured to execute in parallel within encoder layer 504a. Each multi-head attention layer 604 within encoder layer 504a accepts input embedding 602 and identifies substructures corresponding to device components of interest. In embodiments where multiple multi-head attention layers 604 operate in parallel, the outputs produced by the different multi-head attention layers 604 are concatenated into one final output vector. Input embeddings 602 are passed as a residual connection and added to the output vector produced from multi-head attention layers 604 at addition node 606 to produce an internal embedding. This internal embedding is then passed to a feed-forward network 608, which applies additional transformations to the internal embedding to enable more effective processing further downstream. This internal embedding produced by addition node 606 is also passed as a residual connection and added to the feed-forward embedding output from feed forward network 608 at addition node 610 to produce a modified feed-forward embedding. Lastly, this modified feed-forward embedding is passed to a layer normalization node 612, which normalizes the embedding values to produce output embeddings 614.

FIG. 7 is a more detailed illustration of one of the attention modules 604a of FIG. 6, according to various embodiments. As shown, during operation, input embedding 602 is passed simultaneously to query weights 704, key weights 706, and value weights 708. These nodes correspond to learned weight matrices that act in concert to perform an operation analogous to key-value lookup on input embedding 602. Each of query weights 704, key weights 706, and value weights 708 performs a matrix multiplication that produces a new vector: the query, the key, and the value, respectively. The query vector and key vector are passed to matrix multiplication and scale node 710, which multiplies the query vector and key vectors together and normalizes the value of the output. These multiplication operations produce larger values at indices where the query vector and key vector are similar to one another.

Notably, attention module 604 differs from a standard attention module by the inclusion of device relationship information in the form of the modules spatial bias 712 and device placement bias 714. Spatial bias 712 is a learned linear bias term dependent on the graph distance between two devices included in original netlist 402. Device placement bias 714 also is a learned linear bias term dependent on the potential diffusion sharing relationship between two devices included in original netlist 402. Spatial bias 712 and device placement bias 714, along with the output of matrix multiplication and scale node 710, are added together in addition node 716 to produce an output that is then passed to softmax node 718, which, in turn, normalizes the output values to ensure that the output values reside within a probability scale between zero and one. At matrix multiplication node 720, the output of softmax node 718 is then multiplied with a value vector that is produced by the outputs of value weights 708 to generate the final embedding 722. In this process, an operation analogous to an expectation value is performed over the value vector, where values corresponding to larger softmax values have more significant representations relative to values corresponding to smaller softmax values, completing the key-value lookup operation. Structures identified by the query weights produce outputs from the value weights by way of the key weights, thereby enabling attention module 604 to produce complex responses to graph structures beyond simple non-linear transformations.

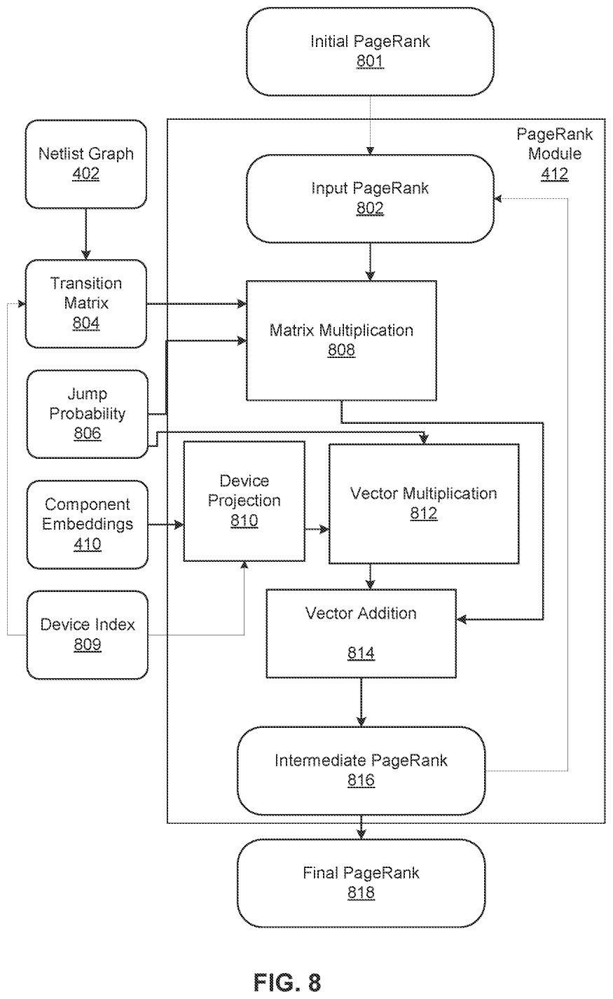

FIG. 8 is a more detailed illustration of the PageRank module 412 of FIG. 4, according to various embodiments. As shown, PageRank module 412 accepts initial PageRank 801, netlist graph 402, component embeddings 410, and device index 809 as inputs. PageRank module 412 produces a final PageRank 818 for a single device included in netlist graph 402 and corresponding to device index 809.

Initial PageRank 801 is a vector initialized to a set of reasonable values (e.g., all zeros or small random values in some embodiments). In operation, initial PageRank 801 is passed into PageRank module 412 and is treated as input PageRank 802 for the first iteration through PageRank module 412. Netlist graph 402 and device index 809 are passed to transition matrix module 804, which transforms the graph information of netlist graph 402 into transition matrix form with information about the connections between nodes in the graph from the perspective of the device included in netlist graph 402 that corresponds to device index 809. The transition matrix produced by transition matrix module 804 is multiplied by input PageRank 802 at matrix multiplication node 808 to produce a transition vector. Component embeddings 410 are passed to device projection node 810, which projects the embeddings of every device included in the netlist graph 402 other than the device corresponding to device index 809 onto the embeddings of the device corresponding to device index 809. That projection is then normalized to produce a predicted cluster probabilities vector. The transition vector and predicted cluster probabilities vector are subsequently multiplied by jump probability 806 and one minus jump probability 806, respectively, to produce a modified transition vector and modified cluster probabilities. The jump probability 806 represents the relative contribution of the component embeddings 410 and the transition matrix in the final PageRank rankings and is a tunable parameter. The modified transition vector and modified cluster probabilities are added together at vector addition node 814 to produce intermediate PageRank 816.

If convergence has not yet been reached, then intermediate PageRank 816 is passed back to input PageRank 802, and the above-described process is performed again. Upon convergence, intermediate PageRank 816 is output from PageRank module 412 as final PageRank 818, which is the final ranking of devices for the device corresponding to device index 809. Convergence may be assessed in any technically feasible way (e.g., sufficient number of iterations, a small enough update between steps).

The operations described above for PageRank module 412 are applied to all devices included in netlist graph 402, where each device included in netlist graph 402 corresponds to a different device index 809. After the above operations are applied to one device included in netlist graph 402, thereby producing a final PageRank 818 for that one device, device indices 809 is incremented to a next value, and the above operations for PageRank module 412 are then applied to the device included in netlist graph 402 corresponding to that next device index 809 value. This process is repeated until the above operations for PageRank module 412 have been applied to all devices included in netlist graph 402 and a separate final PageRank 818 has been computed for each device included in netlist graph 402. The foregoing approach produces a similarity ranking between all devices in netlist graph 402 using information from both component embeddings 410 and the transition matrix produced by transition matrix module 804. The device indices 809 can be generated and accessed in any technically feasible way.

FIG. 9 is a more detailed illustration of the model trainer 116 of FIG. 1, according to various embodiments. As shown, model trainer 116 accepts as input netlist and layout graph pairs 902. Netlist and layout graph pairs 902 include example netlists and routable layout graphs corresponding to those netlists. Netlist and layout graph pairs 902 can be produced by any technically feasible means. As an initial pre-processing step, each of the netlist graphs included in netlist and layout graph pairs 902 is passed through a graph model (not shown) to produce corresponding graph embeddings. Each graph embedding is then passed through transformer model 154 to produce a component embedding. Unsupervised learning module 904 trains transformer model 154 to produce useful embeddings by minimizing a similarity loss function 906 between the component embeddings and the layout graphs from netlist and layout graph pairs 902. In various embodiments, the similarity loss function 906 can be expressed in the following form:

$${L}_{s i m} = {\sum }_{v} ( - {\sum }_{u ∈ N ( v )} log ( σ ( {y}_{v}^{T} {y}_{u} ) ) - {\sum }_{k ∼ rand} log ( - σ ( {y}_{v}^{T} {y}_{k} ) ) ) \qquad ( 1 )$$

where v indexes a device, N(v) is the set of neighbors of device v. Vector yv is the representative embedding of device v, and σ(yvTyu) is the preferred clustering probability of devices v and u. By comparing the clustering probability of neighboring devices in the layout graph to those from random pairs of devices, the similarity loss function 906 causes transformer model 154 to produce higher clustering probabilities for neighboring devices and lower clustering probabilities for non-neighboring devices. Similarity loss function 906 does not require that transformer model 154 produce the exact same layout, but instead asserts that the general structure placement of devices is similar, which enables transformer model 154 to have more general application with less overfitting on the provided training pairs. The derivate of loss function 906 is then computed and backpropagated through the transformer model 154 to update the various weights to minimize loss function 906. This training process is repeated for all pairs in netlist and layout graph pairs 902 multiple epochs until convergence is achieved. Convergence may be assessed in any technically reasonable way (e.g., a certain number of training epochs, a small enough update to the training loss, etc.).

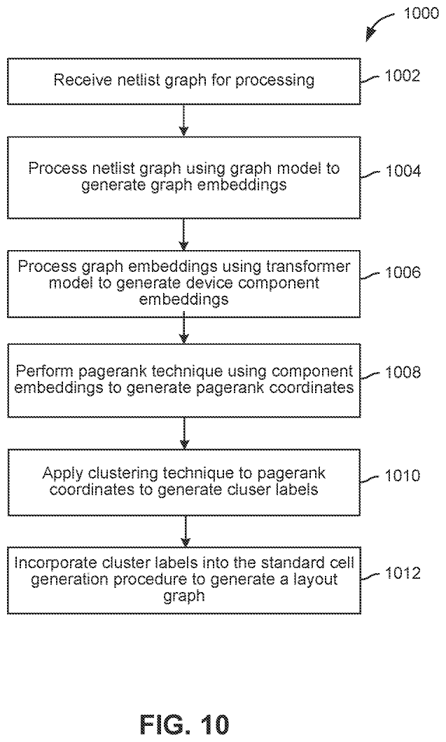

FIG. 10 is a flow diagram of method steps for generating layout graphs from netlist graphs, according to various embodiments. Although the method steps are described in conjunction with the systems of FIGS. 1-9, persons skilled in the art will understand that any system configured to perform the method steps in any order falls within the scope of the present disclosure.

As shown, a method 1000 begins at step 1002, where a netlist graph 402 is received by standard generating application 146 for processing in order to generate a standard cell layout 422 corresponding to netlist graph 402. Netlist graph 402 is a representation of the logical design requirements for an integrated circuit design. In various embodiments, netlist graph 402 may be constructed from a spice netlist, where the devices on the graph are represented as nodes, and the edges between the nodes are derived from the different types of connections (e.g., source-to-net, net-to-gate).

At step 1004, netlist graph 402 is passed through graph model 152 to produce graph embeddings 406. Graph model 152 may accept various properties of netlist graph 402 as inputs to produce graph embeddings 406. For example, node type, device properties, device connectivity, device logic level, and edge properties, could all serve as inputs to graph model 152. Graph embeddings 406 produced by graph model 152 include information about netlist graph 402 that is interpretable by transformer model 154.

At step 1006, graph embeddings 406 are passed through transformer model 154 to produce component embeddings 410. Transformer model 154 maps information pertaining to the logical structure of netlist graph 402 included within graph embeddings 406 to an embedding space. In so doing, transformer model 154 places devices included in netlist graph 402 that should reside closer to one another in standard cell layout 422 closer to one another within the embedding space.

At step 1008, component embeddings 410, along with original netlist graph 402, are passed to PageRank module 412, which produces PageRank coordinates 414.

At step 1010, clustering module 416 accepts PageRank coordinates 414 to produce cluster labels 418. In some embodiments, clustering module 416 implements the DBSCAN clustering algorithm, but, in other embodiments, any technically feasible clustering algorithm may be implemented.

Finally, at step 1012, standard cell module 420 accepts cluster labels 418 and original netlist graph 402 to produce standard cell layout 422. Standard cell module 418 can implement any standard cell generating procedure that has been modified to accept cluster labels 416 as input. For example, a device clustering cost term that counts the number of devices not included within a current cluster within a given region could be added to the objective function of standard cell generating algorithm and implemented in standard cell module 418. Other algorithms that could be used for this type of modification include, without limitation, tree-based methods, simulated annealing, or NVCell.

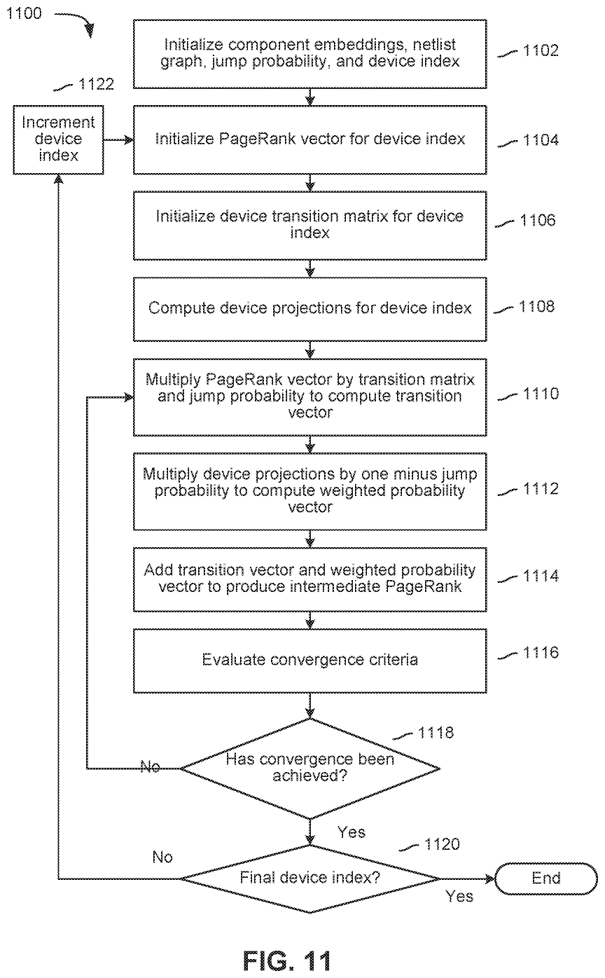

FIG. 11 is a flow diagram of method steps for generating PageRank rankings for devices, according to various embodiments. Although the method steps are described in conjunction with the systems of FIGS. 1-9, persons skilled in the art will understand that any system configured to perform the method steps in any order falls within the scope of the present disclosure.

As shown, method 1100 beings at step 1102, where component embeddings 410, netlist graph 402, jump probability 806, and device index 809 are initialized. As previously described above, PageRank module 412 produces a final PageRank 818 for a single device included in netlist graph 402 corresponding to device index 809. Accordingly, device index 809 is initialized to correspond to the first device included in netlist graph 402.

At step 1104, the initial PageRank 801 for device index 809 is initialized. Initial PageRank 801 is a vector initialized to a set of reasonable values (e.g., all zeros or small random values in some embodiments).

At step 1106, netlist graph 402 and device index 809 are passed to transition matrix module 804, which transforms the graph information of netlist graph 402 into transition matrix form. Notably, the matrix form of the graph information sets forth the connections between the different nodes in the netlist graph 402 from the perspective of the device included in netlist graph 402 corresponding to device index 809.

At step 1108, component embeddings 410 are used to compute device projections 810 for the device included in netlist graph 402 corresponding to device index 809. Device projections measure the similarity between the device corresponding to device index 809 and all other devices in netlist graph 402, and, therefore, the probability of two devices being in the same cluster, as measured by component embeddings 410.

At step 1110, the input PageRank 802 is multiplied by transition matrix 804 and jump probability 806 to produce a modified transition vector. In the first pass through method 1100, initial PageRank 801 is used as input PageRank 802 at step 1110. In each subsequent pass through method 1100, PageRank 816 generated by PageRank module 412 is used as input PageRank 802 at step 1110. At step 1112, device projections 810 is multiplied by one minus jump probability 806 to compute a weighted probability vector. At step 1114, the aforementioned transition vector and probability vector are added together to produce intermediate PageRank 816.

At step 1116 convergence is evaluated using the intermediate PageRank 816. Convergence may be defined in any technically reasonable way (e.g., a certain number of iterations, a small enough update to the final PageRank, etc.). If convergence has not yet been reached, then intermediate PageRank 816 is passed back as input PageRank 802, and the method returns to step 1110. Upon convergence, intermediate PageRank 816 is output from PageRank module 412 as final PageRank 818, which is the final ranking of devices for the device corresponding to device index 809.

At step 1118, if device index 809 corresponds to the final device in netlist graph 402, thereby indicating that each device included in netlist graph 404 has a corresponding final PageRank 818, then method 1100 terminates. If, however, device index 809 is not the final device in netlist graph 402, then device index 809 is incremented at step 1120, and the method returns to step 1104.s

FIG. 12 is a flow diagram of method steps for the unsupervised training of a transformer model on netlist graphs, according to various embodiments. Although the method steps are described in conjunction with the systems of FIGS. 1-9, persons skilled in the art will understand that any system configured to perform the method steps in any order falls within the scope of the present disclosure.

As shown, method 1200 begins at step 1202, where netlist and layout graph pairs 902 are selected for use as training data. Netlist and layout graph pairs 902 include example netlists and routable layout graphs corresponding to those netlists. Netlist and layout graph pairs 902 can be produced by any technically feasible means.

At step 1204, the netlist graphs from netlist and layout graph pairs 902 are passed through transformer model 154 to produce device component embeddings. As an initial pre-processing step, each of the netlist graphs included in netlist and layout graph pairs 902 is passed through a graph model (not shown) to produce corresponding graph embeddings. Each graph embedding is passed through transformer model 154 to produce a device component embedding.

At step 1206, the device component embeddings are compared to the corresponding layout graph from netlist and layout graph pairs 902 via the similarity loss function. Similarity loss function 906 does not require that transformer model 154 produce the exact same layout, but instead asserts that the general structure placement of devices is similar, which enables transformer model 154 to have more general application with less overfitting on the provided training pairs. The derivate of loss function 906 is then computed and backpropagated through the transformer model154 to update the various weights to minimize loss function 906. This process is repeated for all pairs in netlist and layout graph pairs 902.

At step 1208, the convergence criteria are evaluated. Convergence may be defined in any technically reasonable way (e.g., a certain number of training epochs, a small enough update to the training loss, etc.). If the convergence criteria have not been achieved, then the method returns to step 1202, where the above training operations are repeated. If, however, the convergence criteria have been achieved, the method terminates.

In sum, techniques are disclosed for transformer model-based clustering for standard cell design automation. In some embodiments, a netlist logic graph is passed through a graph network model to summarize the logical structure of the netlist graph in graph embeddings. Those graph embeddings then serve as inputs to a transformer model. The transformer model is modified to include additional linear bias terms that incorporate information about the spatial and device placement relationships between netlist graph nodes, and the transformer model is trained on netlist and layout graphs from routable standard cells in an unsupervised fashion using a similarity loss. Upon receiving netlist graph embeddings as input, the transformer model produces device component embeddings for the netlist graph components. The device component embeddings are combined with the transition matrix of the netlist logic graph to create page rank coordinates for each device included in the netlist logic graph. Device clusters are then found based on the page rank coordinates using a clustering algorithm, such as DBScan. Labels for the device clusters are then incorporated into the optimization criteria for a set of sequential standard cell synthesis operations in order to generate one or more standard cell layouts for the initial netlist logic graph.

One technical advantage of the disclosed techniques relative to the prior art is that the disclosed techniques enable integrated circuit designs that incorporate standard cells to be automatically generated in a way that can be more computationally efficient and scalable relative to prior art approaches. Accordingly, the disclosed techniques allow integrated circuits to be automatically designed to have smaller transistor and component sizes and, accordingly, greater complexity relative to what is achievable using prior art approaches. Another technical advantage of the disclosed techniques is the incorporation of circuit-scale information within standard cells, which enables more effective routing when automatically designing integrated circuits. Further, implementing transformer models allows more effective transistor placement within a given circuit relative to prior art techniques, which can result in a greater number of routable design options and a more optimized overall circuit design. These technical advantages provide one or more technological improvements over prior art approaches

1. One embodiment is a computer-implemented method for automatically generating standard cell layouts comprises processing a netlist graph to generate a plurality of graph embeddings; processing the plurality graph embedding via a transformer model to generate a plurality of device component embeddings; generating a page rank value for each device included in the netlist graph based on the plurality of device component embeddings; performing one or more clustering operations on the page rank values to generate a plurality of device clusters; and performing one or more standard cell synthesis operations using labels for the plurality of device clusters to generate at least one standard cell layout for the netlist graph.

2. The embodiment of clause 1, wherein performing the one or more clustering operations further comprises generating the labels for the plurality of device clusters.

3. The embodiment of clause 1 or clause 2, wherein the transformer model includes one or more linear bias terms related to spatial and device placement relationships between nodes included in netlist graphs.

4. The embodiment of any of clauses 1-3, wherein generating the page rank value for each device comprises computing a product of a page rank vector, a transition matrix, and a jump probability to produce a transition vector for a first device included in the netlist graph.

5. The embodiment of any of clauses 1-4, wherein generating the page rank value for each device further comprises computing a product of one or more device projections and a difference between one and the jump probability to produce a weighted probability vector for the first device.

6. The embodiment of any of clauses 1-5, wherein generating the page rank value for each device further comprises computing a sum of the transition vector and the weighted probability vector to produce an intermediate page rank value for the first device.

7. The embodiment of any of clauses 1-6, wherein generating the page rank value for each device further comprises evaluating one or more convergence criteria based on the intermediate page rank value produced for the first device.

8. The embodiment of any of clauses 1-7, wherein generating the page rank value for each device further comprises incrementing a device index if convergence has been achieved, wherein each device index value corresponds to a different device included in the netlist graph.

9. The embodiment of any of clauses 1-8, wherein generating the page rank value for each device further comprises repeating the operations of computing the transition vector, computing the weighted probability vector, and computing the intermediate page rank value for the first device if convergence has not been achieved.

10. The embodiment of any of clauses 1-9, wherein processing the netlist graph comprises passing the netlist graph through a graph network model to summarize a logical structure of the netlist graphs via the plurality of graph embeddings.

11. Another embodiment comprises one or more non-transitory computer-readable media including instructions that, when executed by one or more processors, cause the one or more processors to perform that steps of processing a netlist graph to generate a plurality of graph embeddings; processing the plurality graph embedding via a transformer model to generate a plurality of device component embeddings; generating a page rank value for each device included in the netlist graph based on the plurality of device component embeddings; performing one or more clustering operations on the page rank values to generate a plurality of device clusters; and performing one or more standard cell synthesis operations using labels for the plurality of device clusters to generate at least one standard cell layout for the netlist graph.

12. The embodiment of clause 11, wherein performing the one or more clustering operations further comprises generating the labels for the plurality of device clusters.

13. The embodiment of either clause 11 or clause 12, wherein the transformer model includes one or more linear bias terms related to spatial and device placement relationships between nodes included in netlist graphs.

14. The embodiment of any of clauses 11-13, wherein training the transformer model comprises inputting a plurality of netlist graph/routable layout graph pairs into a version of the transformer model that is not yet fully trained.

15. The embodiment of any of clauses 11-14, wherein training the transformer model further comprises generating a plurality of predicted device component embeddings based on at least one netlist graph included in the plurality of netlist graph/routable layout graph pairs.

16. The embodiment of any of clauses 1-15, wherein training the transformer model further comprises executing a similarity loss function to compare the plurality of predicted device component embeddings to a layout graph corresponding to the at least one netlist graph.

17. The embodiment of any of clauses 1-16, wherein training the transformer model further comprises evaluating one or more convergence criteria based on a comparison between the plurality of predicted device component embeddings and the layout graph to determine whether additional training operations should be performed.

18. The embodiment of any of clauses 1-17, wherein processing the netlist graph comprises passing the netlist graph through a graph network model to summarize a logical structure of the netlist graphs via the plurality of graph embeddings.

19. The embodiment of any of clauses 1-18, wherein generating a page rank value for each device comprises computing a transition vector, computing a weighted probability vector, and computing an intermediate page rank value for each device included in the netlist graph.

20. Another embodiment is a system, comprising one or more memories that include instructions; and one or more processors that are coupled to the one or more memories and, when executing the instructions, are configured to perform the steps of processing a netlist graph to generate a plurality of graph embeddings; processing the plurality graph embedding via a transformer model to generate a plurality of device component embeddings; generating a page rank value for each device include in the netlist graph based on the plurality of device component embeddings; performing one or more clustering operations on the page rank values to generate a plurality of device clusters; and performing one or more standard cell synthesis operations using labels for the plurality of device clusters to generate at least one standard cell layout for the netlist graph.

Any and all combinations of any of the claim elements recited in any of the claims and/or any elements described in this application, in any fashion, fall within the contemplated scope of the present invention and protection.

The descriptions of the various embodiments have been presented for purposes of illustration, but are not intended to be exhaustive or limited to the embodiments disclosed. Many modifications and variations will be apparent to those of ordinary skill in the art without departing from the scope and spirit of the described embodiments.

Aspects of the present embodiments may be embodied as a system, method or computer program product. Accordingly, aspects of the present disclosure may take the form of an entirely hardware embodiment, an entirely software embodiment (including firmware, resident software, micro-code, etc.) or an embodiment combining software and hardware aspects that may all generally be referred to herein as a “module,” a “system,” or a “computer.” In addition, any hardware and/or software technique, process, function, component, engine, module, or system described in the present disclosure may be implemented as a circuit or set of circuits. Furthermore, aspects of the present disclosure may take the form of a computer program product embodied in one or more computer readable medium(s) having computer readable program code embodied thereon.

Any combination of one or more computer readable medium(s) may be utilized. The computer readable medium may be a computer readable signal medium or a computer readable storage medium. A computer readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a computer readable storage medium may be any tangible medium that can contain, or store a program for use by or in connection with an instruction execution system, apparatus, or device.

Aspects of the present disclosure are described above with reference to flowchart illustrations and/or block diagrams of methods, apparatus (systems) and computer program products according to embodiments of the disclosure. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine. The instructions, when executed via the processor of the computer or other programmable data processing apparatus, enable the implementation of the functions/acts specified in the flowchart and/or block diagram block or blocks. Such processors may be, without limitation, general purpose processors, special-purpose processors, application-specific processors, or field-programmable gate arrays.

The flowchart and block diagrams in the figures illustrate the architecture, functionality, and operation of possible implementations of systems, methods and computer program products according to various embodiments of the present disclosure. In this regard, each block in the flowchart or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts, or combinations of special purpose hardware and computer instructions.

While the preceding is directed to embodiments of the present disclosure, other and further embodiments of the disclosure may be devised without departing from the basic scope thereof, and the scope thereof is determined by the claims that follow.

What is claimed is:

1. A computer-implemented method for automatically generating standard cell layouts, the method comprising:
processing a netlist graph to generate a plurality of graph embeddings;
processing the plurality graph embedding via a transformer model to generate a plurality of device component embeddings;
generating a page rank value for each device included in the netlist graph based on the plurality of device component embeddings;
performing one or more clustering operations on the page rank values to generate a plurality of device clusters; and
performing one or more standard cell synthesis operations using labels for the plurality of device clusters to generate at least one standard cell layout for the netlist graph.

2. The computer-implemented method of claim 1, wherein performing the one or more clustering operations further comprises generating the labels for the plurality of device clusters.

3. The computer-implemented method of claim 1, wherein the transformer model includes one or more linear bias terms related to spatial and device placement relationships between nodes included in netlist graphs.

4. The computer-implemented method of claim 1, wherein generating the page rank value for each device comprises computing a product of a page rank vector, a transition matrix, and a jump probability to produce a transition vector for a first device included in the netlist graph.

5. The computer-implemented method of claim 4, wherein generating the page rank value for each device further comprises computing a product of one or more device projections and a difference between one and the jump probability to produce a weighted probability vector for the first device.

6. The computer-implemented method of claim 5, wherein generating the page rank value for each device further comprises computing a sum of the transition vector and the weighted probability vector to produce an intermediate page rank value for the first device.

7. The computer-implemented method of claim 6, wherein generating the page rank value for each device further comprises evaluating one or more convergence criteria based on the intermediate page rank value produced for the first device.

8. The computer-implemented method of claim 7, wherein generating the page rank value for each device further comprises incrementing a device index if convergence has been achieved, wherein each device index value corresponds to a different device included in the netlist graph.

9. The computer-implemented method of claim 7, wherein generating the page rank value for each device further comprises repeating the operations of computing the transition vector, computing the weighted probability vector, and computing the intermediate page rank value for the first device if convergence has not been achieved.

10. The computer-implemented method of claim 1, wherein processing the netlist graph comprises passing the netlist graph through a graph network model to summarize a logical structure of the netlist graphs via the plurality of graph embeddings.

11. One or more non-transitory computer-readable media including instructions that, when executed by one or more processors, cause the one or more processors to perform that steps of:
processing a netlist graph to generate a plurality of graph embeddings;
processing the plurality graph embedding via a transformer model to generate a plurality of device component embeddings;
generating a page rank value for each device included in the netlist graph based on the plurality of device component embeddings;
performing one or more clustering operations on the page rank values to generate a plurality of device clusters; and
performing one or more standard cell synthesis operations using labels for the plurality of device clusters to generate at least one standard cell layout for the netlist graph.

12. The one or more non-transitory computer-readable media of claim 11, wherein performing the one or more clustering operations further comprises generating the labels for the plurality of device clusters.

13. The one or more non-transitory computer-readable media of claim 11, wherein the transformer model includes one or more linear bias terms related to spatial and device placement relationships between nodes included in netlist graphs.

14. The one or more non-transitory computer-readable media of claim 11, wherein training the transformer model comprises inputting a plurality of netlist graph/routable layout graph pairs into a version of the transformer model that is not yet fully trained.

15. The one or more non-transitory computer-readable media of claim 14, wherein training the transformer model further comprises generating a plurality of predicted device component embeddings based on at least one netlist graph included in the plurality of netlist graph/routable layout graph pairs.

16. The one or more non-transitory computer-readable media of claim 15 wherein training the transformer model further comprises executing a similarity loss function to compare the plurality of predicted device component embeddings to a layout graph corresponding to the at least one netlist graph.

17. The one or more non-transitory computer-readable media of claim 16, wherein training the transformer model further comprises evaluating one or more convergence criteria based on a comparison between the plurality of predicted device component embeddings and the layout graph to determine whether additional training operations should be performed.

18. The one or more non-transitory computer-readable media of claim 11, wherein processing the netlist graph comprises passing the netlist graph through a graph network model to summarize a logical structure of the netlist graphs via the plurality of graph embeddings.

19. The one or more non-transitory computer-readable media of claim 11, wherein generating a page rank value for each device comprises computing a transition vector, computing a weighted probability vector, and computing an intermediate page rank value for each device included in the netlist graph.

20. A system, comprising:
one or more memories that include instructions; and
one or more processors that are coupled to the one or more memories and, when executing the instructions, are configured to perform the steps of:
processing a netlist graph to generate a plurality of graph embeddings;
processing the plurality graph embedding via a transformer model to generate a plurality of device component embeddings;
generating a page rank value for each device include in the netlist graph based on the plurality of device component embeddings;
performing one or more clustering operations on the page rank values to generate a plurality of device clusters; and
performing one or more standard cell synthesis operations using labels for the plurality of device clusters to generate at least one standard cell layout for the netlist graph.
